(19) United States
(12) Patent Application Publication
(10) Pub. No.: US 2024/0403521 A1
(43) Pub. Date: Dec. 5, 2024

(54) SCALABLE HARDWARE ARCHITECTURE TEMPLATE FOR PROCESSING STREAMING INPUT DATA

(71) Applicant: Google LLC, Mountain View, CA (US)

(72) Inventors: Yang YANG, Mountain View, CA (US); Aki Oskari KUUSELA, Mountain View, CA (US)

(21) Appl. No.: 18/695,216

(22) PCT Filed: Dec. 10, 2021
(86) PCT No.: PCT/US2021/062817

§ 371 Date: Mar. 25, 2024

(51) Int. Cl. G06F 30/27; H04N 21/233; H04N 21/258

(52) U.S. Cl. CPC G06F 30/27; H04N 21/233; H04N 21/25833

(57) ABSTRACT

Methods, systems, and apparatus, including computer programs encoded on computer storage media for generating an enhanced hardware architecture to process streaming input data are described. In one aspect, a method includes receiving data representing a hardware architecture template (195, 810). The hardware architecture template includes a set of configurable design parameters. Values for the set of design parameters are determined based on characteristics of the streaming input data (820). The determination process includes generating multiple candidate hardware architectures based on a search space for the set of configurable design parameters (840), each candidate hardware architecture including respective design parameter values, determining respective performance values associated with each candidate hardware architecture (850), selecting a hardware architecture based on the respective performance values (860), and determining the values based on parameter values associated with the selected candidate hardware architecture (870). The output data including the values is generated for instantiating the hardware architecture using the hardware architecture template.

### TECHNICAL FIELD

This specification relates to using a scalable hardware architecture template to generate hardware design parameters for hardware components, e.g., machine learning processors, that perform operations on streaming input data and using the parameters to manufacture the processors.

### BACKGROUND

Artificial intelligence (AI) is intelligence demonstrated by machines and represents the ability of a computer program or a machine to think and learn. One or more computers can be used to perform AI computations to train machines for respective tasks. AI computations can include computations represented by one or more machine learning models.

Neural networks belong to a sub-field of machine-learning models. Neural networks can employ one or more layers of nodes representing multiple operations, e.g., vector or matrix operations. One or more computers can be configured to perform the operations or computations of the neural networks to generate an output, e.g., a classification, a prediction, or a segmentation for a received input. Some neural networks include one or more hidden layers in addition to an output layer. The output of each hidden layer is used as input to the next layer in the network, i.e., the next hidden layer or the output layer. Each layer of the network generates an output from a received input in accordance with current values of a respective set of network parameters.

### SUMMARY

The techniques described in the following specification are related to using a scalable hardware architecture template to generate hardware design parameters for hardware components, e.g., machine learning processors, that perform operations on streaming input data and using the parameters to manufacture the processors. The hardware architecture template can include a set of configurable design parameters for manufacturing hardware components that can be configured to perform operations on streaming input data, such that the architecture can be scaled up or down based on characteristics of the streaming input data. The techniques can be used to determine values for the set of design parameters and instantiate a hardware architecture using the hardware architecture template and the determined values.

A hardware architecture, also referred to as a hardware architecture representation, generally relates to a representation of an engineered (or to be engineered) electronic or electromechanical hardware block, component, or system. The hardware architecture can encompass data for identifying, prototyping, and/or manufacturing such a hardware block, component, or system. A hardware architecture can be encoded with data representing a structure for the block, component, or system, e.g., data identifying sub-components or subsystems included in the hardware block, component, or system and their interrelationships. A hardware architecture can also include data representing a process of manufacturing the hardware block, component, or system, or data representing a discipline for effectively implementing the designs for the hardware block, component, or system, or both.

The term “hardware architecture template” in this document refers to data representing a template that has a set of design parameters for a hardware component, such as a machine learning processor configured to perform machine learning computations on streaming input. A hardware architecture template can be a pre-set general design for a hardware architecture with multiple aspects to be tailored or customized based on the set of design parameters, e.g., types, quantities, or hierarchies of different computing units to be included in the hardware architecture.

A hardware architecture template can be an abstraction and not instantiated until values for the set of design parameters are determined. After determining the values for the design parameters, e.g., using various processes described in this document, the hardware architecture template can be used for instantiating a hardware architecture based on the determined values for the set of design parameters. In some implementations, the hardware architecture template can represent data encoded in a high-level computer language that can be synthesized to hardware circuits and programmed in an object-oriented fashion, e.g., C or C++. For simplicity, the term “hardware architecture template” is sometimes referred to as “template” in this document.

The set of design parameters can form or have a “search space” in multiple dimensions within which searching respective values for the set of design parameters is performed given particular design requirements or criteria. The values for the design parameters can be determined by exploring the search space using one or more algorithms or techniques. In this document, the term “search space” refers to a solution space encompassing all, or at least a set of, possible solutions (e.g., values) for the set of the design parameters given available resources, for example, all possible types and quantities of different computing units included in a hardware architecture.

The template can be re-configured based on characteristics of data used for performing the computations operations. In some situations, a hardware architecture generated by the template can be re-instantiated on the fly due to a change of input data, e.g., a different input matrix with a different sparsity level.

The term “hardware component” refers to hardware components for performing computing operations, e.g., machine learning computations, including, for example suitable hardware computing units or clusters of computing units configured to perform vector reductions, tensor multiplications, basic arithmetic operations, and logic operations based on the streaming input data. For example, the hardware components can include one or more tiles (e.g., multiply-accumulate operation (MAC) units), one or more processing elements including multiple MAC units, one or more clusters including multiple processing elements, and processing units such as Graphic Processing Units (GPUs) and Tensor Processing Units (TPUs).

The term “streaming input data” refers to data that is continuously provided to a hardware component for processing the data. For example, the data can include multiple frames of data with each frame generated at a particular time interval, and each frame of data is provided to a hardware component for processing at a particular rate. The terms “time interval” and “rate” refer to a time period or a frequency for generating or receiving a frame and a next frame of data. For example, a rate for streaming input data can be one frame of data per a few milliseconds, seconds, minutes, or other appropriate time periods.

Streaming input data can be streaming image frames or video frames collected by an image sensor according to a time sequence. The image sensor can include a camera or a recorder. The streaming image frames can be collected by the image sensor at a particular rate, or provided to a hardware component at a particular arrival rate.

Each frame of the streaming input data can have a particular size. For example, each of the streaming image frames can include a respective image resolution, e.g., 50 by 50 pixels, 640 by 480 pixels, 1440 by 1080 pixels, or 4096 by 2160 pixels.

A hardware component can be configured to process streaming input data received at a particular rate. As described above, streaming input data can be continuously generated frame by frame, e.g., from one or more sources, and provided to the hardware component at a particular arrival rate. For example, the rate can be a frame per unit time, or a quantity of pixels per unit time. Ideally, the hardware component can process each frame of streaming input data before the arrival of the next frame of input data to generate output data in time. However, if the hardware component cannot process the frame before the arrival of the next frame, the hardware component can result in backpressure for processing the following frames of streaming input data. The backpressure can cause interruptions or time delays for generating output data, increase system overheads, in particular when other hardware components in a system are configured to process the output data generated by the hardware component, or cause errors in the operation of the hardware components and/or the computations made by the hardware components.

In some implementations, a system can generate output data with higher accuracy using new streaming input data with a larger frame size, or at a higher frequency, or both (e.g., more frames of images per unit time with a higher resolution per image). An initially-suitable hardware component can be rendered incompetent of processing each frame of the new streaming input data before the arrival of next frame, which causes backpressure for processing later arriving frames of the streaming input data.

Techniques to perform Generalized Matrix Multiplication (GEMM) and Generalized Matrix Vector Multiplication (GEMV) cannot be applied in processing streaming input data because each frame of the streaming input data is received in a sequence. For example, each frame of streaming input data can be represented by an input matrix, and the input matrix is received by the hardware component row by row during a particular time window. An example of the GEMM or GEMV techniques is known as loop tiling, also referred to as loop nest optimization, which partitions a loop's iteration space into smaller chunks or blocks for performing matrix-matrix or matrix-vector computations, so that each smaller chunk or block of the inputs can be computed in parallel. However, the loop tiling technique is unlikely to be adapted for processing streaming input data because the input is received row by row according to a sequence. It is impossible or at least impractical to store in advance a last row of a current frame or a row of a next frame and perform operations on these rows while processing a different row in the current frame in parallel.

Some techniques resort to solving the backpressure problem by including more processing elements (PEs) or computing units when the streaming input data increases in size or frequency. However, it might be inefficient, un-scalable, and can soon reach a maximum power requirement for a hardware component when the frame sizes or the arrival rates scale up. For example, edge devices (e.g., smart phones, tablets, laptops, and watches) configured to process the streaming input data (e.g., perform computations using each frame of the input data) might have an upper limit for power consumption rate. The total quantity or number of computing units integrated within a hardware component for an edge device can thus be bounded by a maximum power requirement, or a requirement for the battery life per charge, or both.

To process streaming input data more efficiently and robustly with high throughput, the techniques described in this document implement a hardware architecture template with a set of design parameters. A system performing the described techniques can determine values for the set of design parameters based on characteristics of the streaming input data and instantiate a hardware architecture using the hardware architecture template with the determined design parameter values. The hardware architecture includes a particular arrangement of computing units specified by the design parameter values and represents a hardware component suitable for processing the streaming input data. The hardware architecture can be used for manufacturing the hardware component.

According to one aspect, the document describes a method for generating a hardware architecture based on a particular streaming input data. The hardware architecture can be used to manufacture a hardware component that can satisfactorily process the particular streaming input data. The method includes receiving data representing a hardware architecture template with a set of configurable design parameters, where the set of design parameters can include two or more of a quantity of clusters, a quantity of processing unit s in each cluster, and a size of a hardware unit array in each processing unit.

The method further includes determining values for the set of configurable design parameters based at least in part on characteristics of streaming input data to be processed by the hardware component. The determining process includes: generating multiple candidate hardware architectures using a search space for the configurable design parameters, determining respective values for a set of performance measures associated with each candidate hardware architecture, selecting one candidate hardware architecture from all of the multiple candidate hardware architectures based at least in part on the respective values for the set of performance measures, and determining values for the design parameters based on the selected candidate hardware architecture.

The output data generated by the method can include at least the design parameter values for manufacturing the hardware architecture.

In some implementations, the method includes providing the output data to the hardware architecture template, instantiating a hardware architecture based on the determined design parameter values, and manufacturing a hardware component using the hardware architecture.

In some implementations, the characteristics of the streaming input data can include an arrival rate of each frame and a size of each frame. The set of performance measures can include measures at least one of latency, power consumption, resource usage, or throughput for processing the respective streaming input data for the given hardware component. The performance models can include at least one of an analytical cost model, a machine learning cost model, or a hardware simulation model. The streaming input data can be streaming image frames collected by an image sensor according to a time sequence. The characteristics of the streaming image frames can include a particular arrival rate, where each frame of the streaming image frames can have a respective image resolution. In some implementations, the characteristics of the streaming image frames can include respective image resolutions for image frames. The characteristics of the streaming image frames can include a blanking period (e.g., a vertical blanking period and/or a horizontal blanking period), a pixel or color format (e.g., a RGB or YUV color format), and an order of arrival for image frames. The streaming input data can be streaming audio collected by an audio sensor according. The characteristics of the audio streaming data can include at least one of a particular sample rate for the streaming audio, a bit depth of the streaming audio, a bit rate of the streaming audio, or an audio format of the streaming audio.

In some implementations, the streaming input data can be received in matrix or vector form. The method further includes segmenting a frame of input from a matrix into multiple vectors, decomposing a matrix by matrix multiplication into multiple vector by matrix multiplications, determining a sparsity level of a matrix (e.g., a matrix stored in a memory unit and used for multiplying with the streaming input data), and/or determining non-zero values in the stored matrix to improve the computation efficiency.

Particular embodiments of the subject matter described in this specification can be implemented to realize one or more of the following advantages. The techniques described in this document can be robust to generate hardware components, e.g., machine learning processors, that are capable of processing different streaming data with different frame sizes and arrival rates. More specifically, a system performing the described techniques can customize a hardware architecture for particular streaming input data by determining design parameter values of a hardware architecture template. The techniques can determine the parameter values quickly to enable agile hardware development. The hardware architecture template can be used to instantiate a hardware architecture based on the determined design parameter values, allowing for scalable and customizable hardware architectures that are capable of supporting streaming input data having wide variations in data rates, data sizes, and/or other characteristics. The instantiated hardware architecture can be enhanced to reduce and even eliminate back pressure when processing the particular streaming input data. The hardware architecture can be configured to be re-instantiated on the fly to process different matrices that are non-streaming and have different sparsity levels up to a sparsity level of 50%.

In addition, the techniques described in this document improve the efficiency for processing streaming input data. More specifically, the described techniques can use less computational resources, less power, and less memory to perform computations, e.g., machine learning computations, on streaming input data. The design parameter values for the template are determined based on one or more factors, requirements, or criteria, e.g., the design parameter values can be determined to minimize power usage and sustain a particular input arrival rate. For example, the design parameters can be determined such that the streaming input data can be processed without backpressure while still meeting power and/or size requirements for the hardware component. A system performing the described techniques can also perform particular treatments to sparse matrices to reduce memory usage. For example, the system can refrain from storing zero-values of non-streaming matrices for processing the streaming input data, and performing operations only on input values that are associated with the non-zero values of the non-streaming matrices, which reduces computations resources for performing the operations, and reduces memory bandwidth for data transfer and memory size for storage.

Furthermore, the techniques described in this document can process streaming input data with high throughput and performance. The described techniques can reduce latency in processing the streaming input data by balancing the processing speed and the computing unit idle time according to different processing requirements. For example, a hardware component generated by the template can process each frame of the streaming input data at a faster speed and might cause more idle time for one or more computing units in the hardware component. Alternatively, the hardware component can process each frame at a reduced speed but is still capable of processing each frame in time. The described techniques can also guarantee a high throughput by avoiding potential logic congestion or decreased hardware clock rate. For example, the described techniques can explore only a subset of the set of design parameters until the generated hardware architecture reaches a scalability limit, where further increasing the values for the subset of design parameters would result in logic congestion or adversely affect hardware clock rate.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example architecture design system.

FIG. 2 illustrates an example scenario for processing a frame of streaming input data.

FIG. 3 illustrates another example scenario for processing a frame of streaming input data.

FIG. 4 illustrates another example scenario for processing a frame of streaming input data.

FIG. 5 illustrates another example scenario for processing a frame of streaming input data.

FIG. 6 illustrates an example data access pattern for a non-streaming matrix.

FIG. 7 is an example process of processing a sparse non-streaming matrix.

FIG. 8 is a flow diagram of an example process of generating an output data using a hardware architecture template.

Like reference numbers and designations in the various drawings indicate like elements.

### DETAILED DESCRIPTION

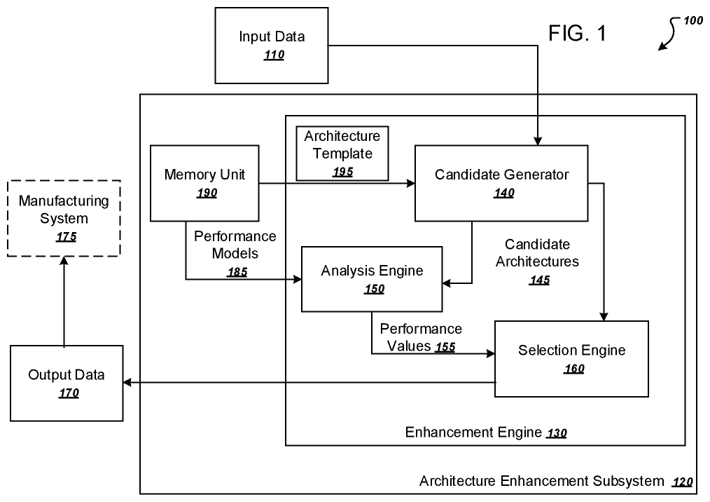

FIG. 1 illustrates an example architecture design system 100. The architecture design system 100 is an example of a system implemented on one or more computers in one or more locations, in which systems, components, and techniques described below can be implemented. Some of the components of the architecture design system 100 can be implemented as computer programs configured to run on one or more computers.

As shown in FIG. 1, the architecture design system 100 can include an architecture enhancement subsystem 120 configured to process input data 110 to generate output data 170 associated with an enhanced hardware architecture for a hardware component.

More specifically, the output data 170 can be used to instantiate a hardware architecture and the hardware architecture can be used to manufacture a hardware component configured to process streaming input data, e.g., a streaming of images. The hardware component can be configured to perform different operations to process the streaming input data, for example, operations of machine learning computations using a matrix or a vector stored by the component and the streaming input data. The streaming input data can be in vector, matrix or tensor form. The hardware component can be a graphic processing unit (GPU), a tensor processing unit (TPU), an application-specific integrated circuit (ASICs), or another appropriate processing unit or circuit configured to satisfactorily process the streaming of images.

As an example, a hardware component can be part of a client device or an edge device, such as a smartphone, a computer, a portable tablet, etc. that is designed with one or more computation units configured to process a streaming input data, e.g., a streaming of images or video. The streaming input data can be received by the hardware component frame by frame at a defined time interval, and be processed by the edge device according to the receiving order, e.g., using other data stored at the edge device. For example, the edge device can perform inference operations of a neural network to process an input video frame by frame to recognize faces using network weights stored at the edge device.

The input data 110 can include data representing characteristics of streaming input data to be processed by a hardware component with a particular hardware architecture. The characteristics can include a particular receiving rate for the streaming input data. For example, the receiving rate can be one frame per millisecond, second, minute, or other appropriate unit of time. In some implementations, the streaming input data can include multiple image frames, e.g., of a video. The characteristics can further include a particular data size for each frame received at a time step. For example, the data size can be a pixel resolution of 720 by 480 pixels, 1280 by 720 pixels, 1920 by 1080 pixels, 4096 by 2160 pixels, or more, when each frame is an image frame. In another example, the data size for each frame can be a quantity of bits or bytes of each frame. For example, when the frames are other types of data, the data size can be expressed in bits or bytes.

The input data can also include other characteristics. One example of the characteristics can be a blanking period of a sensor configured to receive the streaming input data. The blanking period can include a vertical blanking period, a horizontal blanking period, or both. The blanking period generally refers to a time period between a time at which a sensor receives an end of the final visible line (e.g., a bottom or a left line) of a frame or field and a time at which the sensor receives a beginning of the first visible line (e.g., a top or a right line) of the next frame. In one particular example, the blanking period's frequency (i.e., the inverse of the time period) can be 60 Hz for the vertical blanking period and 15,750 Hz for the horizontal blanking period. Other frequencies can also be used. The processing rate of a hardware component is therefore ideally to accommodate the blanking period of the streaming image frames.

Another example characteristic can be the pixel format (or color format) of the streaming input image data, e.g., RGB or YUV. In addition, the characteristics of the streaming input data can include an order of arrival for each frame of the streaming input data.

The streaming input data can also be audio data or signal. For example, audio data can include a recording of one or more speeches produced by one or more individuals, a recording of sound, background noise, or other appropriate type of audio data. The streaming audio data can include audio captured by a smart speaker or other type of digital assistant device. The streaming audio input can include podcasts, radio broadcasts, and/or other types of audio that can be captured by an audio sensor, e.g., a microphone.

The streaming input data can include different characteristics of streaming audio input data. For example, the characteristics for streaming audio can include a sampling rate. The sampling rate generally refers to a sampling frequency of analog signal sampled from the audio signal using an audio sensor, i.e., a quantity of sample analog signal collected per unit of time. The sampling rate can be 44.1 KHz, 48 KHz, 88.2 kHz, 96 KHz, 192 KHz, or more. As another example, the characteristics of streaming audio input data can include a bit depth. The bit depth generally refers to a bit size per audio sample, which sometimes is also referred to as an audio resolution for an audio sample. The bit depth can be 4 bits, 16 bits, 24 bits, 64 bits, or other appropriate bit depths. In some implementations, the characteristics of streaming audio input data can include a bit rate. The bit rate generally refers to a quantity of bits that are conveyed or processed per unit of time. The bit rate can be calculated based on the sampling rate and the bit depth, for example, a digital audio compact disc audio (CD) can have a bit rate of 1.4 Mbit/s when the CD has a sampling rate of 44.1 KHz, a bit depth of 16 bit, and double tracks. The processing rate of a hardware component is ideally faster than the bit rate of the audio streaming input data to avoid backlogging when the hardware component processing the streaming input audio.

Other characteristics for the audio streaming input data can include audio formats for the data. For example, audio streaming input data can be encoded in an audio format of Pulse-Code Modulation (PCM), MPEG-1 Audio Layer 3 (MP3), Windows Media Audio (WMA), or other appropriate audio formats.

In some implementations, the input data 110 can include streaming input data to be processed by a hardware component, e.g., a machine learning processor that performs machine learning computations. The architecture enhancement subsystem 120 can be configured to analyze the streaming input data to generate data representing characteristics of the streaming input data, e.g., a receiving rate or arrival rate of each frame and a size of each frame.

Optionally, the input data 110 can also include data representing initial values for the set of configurable design parameters for instantiating the hardware architecture template. The initial values can be used to instantiate a default architecture, e.g., an architecture including one MAC unit per cluster. The default architecture can include, for example, a static random access memory (SRAM)-based line buffer unit in a cluster, where the line buffer unit has a single memory bank and is configured to store an entire line of input pixels of each frame. As another example, the initial values can include data indicating zero accumulator arrays in a default architecture.

Although streaming input data in the above examples is a stream of image frames, it should be appreciated that the streaming input data can include different types of data such as audio recordings, data structures such as vectors and tensors, to name just a few examples.

The output data 170) can include at least a set of enhanced parameter values for instantiating or re-instantiating a hardware architecture using the architecture template. The set of enhanced parameter values are determined for a set of design parameters of the architecture template. The design parameters can include at least a quantity of clusters in a hardware architecture, a quantity of PEs in each cluster, a size of a MAC array in each processing element (PE), or any combination of two or more of these parameters. For example, the size of a MAC array can be 1, 4, 10, or more. As another example, the quantity of PEs in each cluster can be 1, 4, 7, 20, 50, or more. As another example, the quantity of clusters in a hardware architecture can be 1, 2, 8, 15, 30, or more. In some implementations, the output data 170) can include data defining the enhanced hardware architecture, including the set of enhanced parameter values and any other data that defines how the hardware component should be manufactured.

The output data 170 can be encoded in a high-level computer language that can be synthesized into hardware circuits and programmed in an object-oriented fashion, e.g., C or C++, as described above. In other examples, the output data 170 can be a list of the enhanced parameter values.

The output data 170 can be provided for a manufacturing system 175 to produce a hardware component having a hardware architecture that is instantiated by the template using the parameter values in the output data. The manufacturing system 175 can be any suitable system for manufacturing the hardware component, e.g., a fabrication system or a chemical-mechanical polishing system,

The architecture enhancement subsystem 120 can include an enhancement engine 130 configured to generate the output data 170 by processing an architecture template 195 based on the input data 110. For example, the architecture enhancement subsystem 120 can include a memory unit 190 configured to store and provide data representing the architecture template 195 to the enhancement engine 130. Alternatively, the enhancement engine 130 can receive the architecture template 195 from a server or a memory unit that is external to the architecture enhancement subsystem 120.

The architecture template 195 can be a high-level program code with multiple configurable design parameters. The architecture template 195 is configured to receive a set of design parameter values, and once executed by the system, can generate an output data representing a hardware architecture used for manufacturing a hardware component for processing a particular type of streaming input data. For example, the enhancement engine 130 can provide multiple sets of design parameter values to the architecture template 195 and generate multiple candidate architectures 145.

The enhancement engine 130 includes a candidate generator 140 that is configured to generate multiple candidate architectures 145. The candidate generator 140 can process the input data 110 and the architecture template 195 to generate the multiple candidate architectures 145. The candidate generator 140 is configured to explore multiple parameter values in a search space formed by the set of design parameters given available resources for a particular time period. The search space can have a size ranging from ten, a few hundred, tens of thousands of design points (e.g., tuples that each include respective values for all design parameters), or other appropriate numbers of design points, depending on the targeted computation requirements for process the streaming input data. For each set of candidate design parameter values obtained by the exploration, the candidate generator 140 can instantiate a corresponding hardware architecture using the architecture template 195. The details of exploration of a search space are described below.

The enhancement engine 130 also includes an analysis engine 150 that is configured to analyze candidate architectures 145 and generate a performance value 155 for each candidate architecture 145 using one or more performance models 185. For example, the performance values can include any suitable numeric value, e.g., a scalar value ranging from 0 to 100, that indicates a performance of the candidate architecture 145 in processing the streaming input data. For example, the performance value 155 for a candidate architecture 145 can indicate how efficient the candidate hardware architecture 145 is when used for processing the streaming input data. For example, the efficiency can be based on the computation speed, a percentage of time in backpressure situations, data processing rate, or power or space consumption relative to the data processing rate for those architectures that meet the data processing rate requirement to avoid backpressure. It is not uncommon for a hardware architecture to be predicted to have a high performance value (e.g., 90 out of 100) when processing a first streaming input data, but a low performance value (e.g., 30 out of 100) when processing second streaming input data that has different characteristics than the first streaming input data. Therefore, by generating performance values associated with multiple, e.g., all, candidate architectures for processing a particular streaming input data, the system 100 can efficiently obtain one or more of the best performing candidate architecture designs for processing the particular streaming input data using the architecture template 195.

The performance model 185 can be an analytical, a machine-learning based, or a simulative model configured to access different aspects of the performance for a hardware architecture to process a particular type of streaming input data. The performance metrics can measure different aspects of the hardware architecture, e.g., power consumption, resource usage, throughput, or whether there would be any backpressure when processing streaming input data having the characteristics indicated by the input data 110.

The performance model 185 can be represented in data stored in the memory unit 190 in the architecture enhancement subsystem 120 or provided by an external memory unit or a server.

The selection engine 160, as shown in FIG. 1, can be configured to select a candidate architecture from the multiple candidate architectures 145 as an enhanced hardware architecture based on the performance values 155. For example, the selection engine 160 can select a candidate architecture with the highest performance values 155 as the enhanced candidate architecture. As another example, the selection engine 160 can select a candidate architecture with a performance value 155 above a specified, e.g., predefined, threshold value and uses the least power, or resources, or both. For example, the selection engine 160 can filter from the candidate architectures 145 each candidate architecture that has a performance value 155 that does not meet or exceed the specified threshold value. The selection engine 160 can then select, from the remaining candidate architectures, a particular candidate architecture based on their performance values, power consumption estimates, required resources and/or space on circuit board(s), etc. For example, the selection engine 160 can select the remaining candidate architecture 145 that consumes the least amount of power and/or requires the least amount of space.

In another example, the selection engine 160 can filter the candidate architectures 145 based on power consumption and/or required space. For example, a device for which the hardware component is being designed can have limited available power and/or space, e.g., especially if the device is a smart phone or other mobile device. In this example, the selection engine 160 can filter, from the candidate architectures 145, each candidate architecture 145 that would exceed the available power or space. The selection engine 160 can then select from the remaining candidate architectures 145 based on performance values 155, e.g., by selecting the remaining candidate architecture having the highest performance value 155.

The selection engine 160 can encode the enhanced hardware architecture, or the enhanced parameter values, or both into the output data 170 for further operations. For example, the enhanced parameter values can be provided to multiple computers for instantiating the enhanced hardware architecture in parallel. As another example, the enhanced hardware architecture can be provided to one or more manufacturing apparatus to manufacture corresponding hardware components, e.g., in parallel, based on the enhanced hardware architecture.

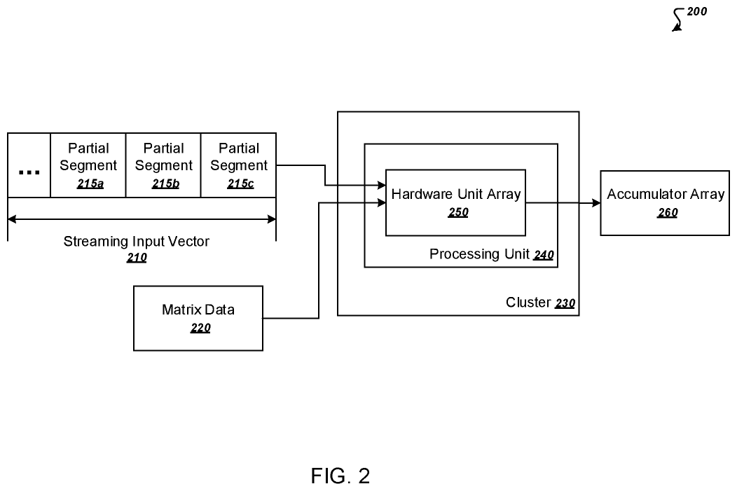

FIGS. 2-5 illustrate example scenarios in which example hardware components having different designs process a frame of streaming input data. For convenience, the above-noted processes are described as being performed by a hardware component of one or more computers located in one or more locations. For example, a hardware component manufactured using the architecture design system 100 of FIG. 1, appropriately programmed, can perform these processes.

The described hardware component manufactured using the template is configured to process the streaming input data with different levels of designs. For example, the hardware architecture can have a first level design for clusters, a second level design for processing elements (also referred to as processing unit in this document), and a third level design for hardware unit arrays (also referred to as hardware computing unit arrays, or hardware computing arrays below, e.g., MAC unit arrays). The described hardware architecture can be instantiated from a template after determining each level of design. For example, the design parameters can include a quantity and/or arrangement for the cluster, a quantity and/or arrangement of the PEs in each cluster, and/or a quantity of hardware unit arrays in each PE. As another example, the design parameters correspond to a dimension of each hardware unit array, e.g., a dimension or quantity of hardware units (e.g., MAC units) in a hardware unit array.

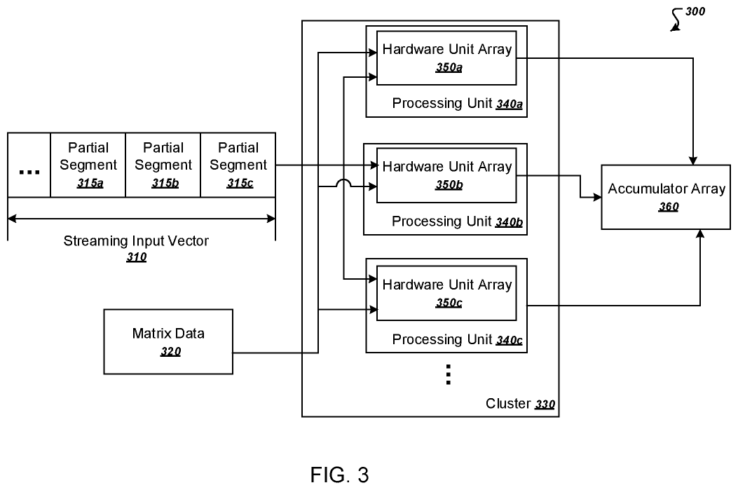

As shown in FIG. 2, an example hardware architecture 200 can include one cluster 230 that includes one processing unit 240. The processing unit 240 can include a hardware computing unit array 250. As another example, hardware architecture 300 shown in FIG. 3, each cluster 330 can include multiple processing units 340a-c, each processing unit 340a-c having one hardware unit array 350a-c, respectively. In addition, another example of hardware architecture 400 can include multiple clusters 430a, 430b. Each cluster 430a and 430b can include a processing unit 440a and 440b. Each processing unit 440a and 440b can include one hardware unit array 450a and 450b respectively. Furthermore, another example of hardware architecture 500 can include multiple clusters 530a-x, each cluster having multiple processing units 540a-x, each processing unit 540a-x including a hardware unit array 550a-z. Although for each hardware architectures 200-500, there are only two, three, or four clusters, processing units, or hardware unit arrays depicted in FIGS. 2-5 for the ease of illustration, it should be appreciated that a hardware architecture can include other quantities of clusters, processing units, and hardware unit arrays.

The hardware architecture can be configured to process a frame of streaming input data per unit time, e.g., at a time step for each frame. Each frame of the streaming input data can be received in a vector form with multiple dimensions, e.g., a vector of 2, 5, 10, or 20 entries. The dimension of the input vector can be 1×input_{dim}. Alternatively, each frame of streaming input data can be received in a matrix form, which can be processed as vectors by breaking the input matrix into multiple vectors.

Generally, the hardware architecture can perform operations on the input vectors with a pre-stored matrix or vector. The pre-stored matrix can be structured as a matrix with dimensions, e.g., input_{dim}×output_{dim}. In some implementations, the operations include vector or matrix multiplication, therefore the output data generated by the hardware architecture can be in a vector form with a dimension of 1×output_{dim}. Or, the output can be in matrix form, e.g., if the operations include matrix-matrix multiplication.

After determining the hardware architecture based on the design parameter values using the described template, a hardware component or system manufactured based on the described hardware architecture can divide each frame of streaming input data (e.g., an input vector) into one or more partial tiles based on a dimension a hardware unit array, e.g., a quantity of MAC units in an array. For example, assuming a MAC unit array includes D MAC units in the array, the dimension of each input tile can be a dimension D. The partial tiles are also referred to as partial segments in the following specification. Each partial tile includes non-overlapping values of the input vector.

Referring back to FIGS. 2-5, the streaming input can be received in a matrix or vector form frame by frame. If the streaming input of a frame is received in a matrix form, a controller or a scheduler can remap or reshape the input matrix into an elongated vector or multiple vectors for further processing by the hardware component. For example, if each frame of the streaming input data is received in a matrix form, the controller or scheduler can treat each row of the matrix as a vector, and transform the computations from the matrix by matrix multiplication into the vector by matrix multiplications. The other matrix that is multiplied by the input matrix or vectors is a matrix that is stored in a memory unit, e.g., rather than being additional streamed input data.

The streaming input vector 210 can be divided into multiple non-overlapping partial segments 215a-215c, each having a dimension D corresponding to the size of hardware unit array 250. A controller or a scheduler (e.g., a hardware hierarchical state machine) in the system can generate these segments 215a-c and schedule operations using these segments to be performed in different clusters, PEs, and MAC unit arrays. Similarly, streaming input vector 310, 410, and 510 can be divided into multiple partial segments 315a-c, 415a-c, and 515a-c, respectively. Although there are only three partial segments shown in FIGS. 2-5, it should be appreciated that each frame of the input vector for a time step can be divided into more than 3 partial segments, e.g., 4, 8, 12, 24, 51, or another appropriate number of partial segments.

In general, the dimension D can be the same or smaller than the input_{dim}, which is the column or row length of the input matrix stored in the hardware component. For example, a frame of streaming input data can have an input dimension of 100. Each partial tile and a corresponding hardware unit array can have a dimension of 1, 10, 20, 50, 100, or another appropriate dimension.

The component or system can store all of the partial segments in one or more buffers, e.g., buffers in a processing unit that includes the hardware unit array.

The hardware component or system can be configured to perform operations over each input partial tile based on a vector of size D that is fetched or pre-fetched from a corresponding row or column of the pre-stored matrix (e.g., a partial row or column corresponding to the partial tile). Referring back to FIGS. 2-5, the pre-stored matrix can be the matrix data 220, 320, 420, and 520, respectively. The operations can include, for example, dot product and other suitable element-wise arithmetic operations. The hardware component or system can generate a partial output (e.g., a partial sum) by performing the above-noted operations at this time step and store the partial output in an accumulator array, e.g., the accumulator array 260, 360, 460, and 560 shown in FIGS. 2-5, respectively.

The hardware component or system can repeatedly perform the above-noted operations for each input partial tile and the corresponding partial row or column of the pre-stored matrix. The total times of repetition can be based on the design parameters, e.g., different quantities of clusters, PEs, hardware unit arrays and the dimension D of each hardware unit array.

For example and referring back to FIG. 2, for each frame of streaming input data, the hardware component or system can repeat the above-noted operations for output_{dim} times. Therefore, the size of the accumulator array can be output_{dim} for storing all the partial outputs. The accumulator array 260 can aggregate the stored partial outputs and provide the aggregated outputs for further operations.

As another example and referring back to FIG. 3, the hardware architecture 300 can include multiple processing units 340a-c in a cluster 330. Assuming each processing unit 340a-c can have a hardware unit array 350a-c (MAC array) of size 1, e.g., only a single MAC unit in each hardware unit array 350a-c, then the quantity of MAC arrays equals the quantity of processing units 340a-c in the cluster 330. The described hardware component or system can divide the input vector into multiple partial tiles each having a dimension of one element because the hardware unit array has a dimension of one.

Assuming the output dimension is greater than or equal to the quantity of processing units, one or more processing units can be used to perform more than one partial tiles, i.e., a number of output_{dim}/#of PES output dim partial tiles. Each processing unit can have an accumulator array with a size of output_{dim}/#of PES. For example, the output dimension is 10 and the quantity of processing units 350 per cluster is 5, then each processing unit 350 is used twice for processing two partial input tiles respectively, and each processing unit 350 can have an accumulator array 360 with a size of 2. The processing units in FIG. 3 are designed to be equal to or less than the output dimensions for computation resources efficiency.

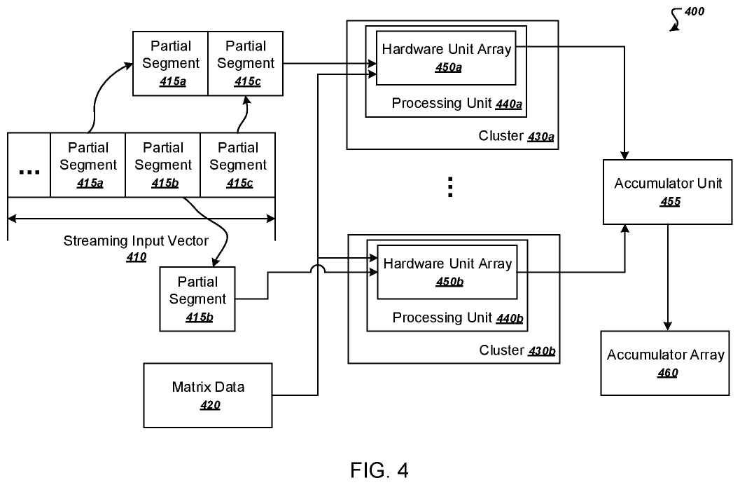

Referring to FIG. 4, the example hardware architecture 400 can include multiple clusters, e.g., two clusters 430a and 430b. The streaming input vector 410 is divided into multiple partial segments 415a-c. Each of the multiple partial segments 415a-c has a dimension as the hardware unit array(s) 450a and 450b.

The multiple partial segments 415a-c can be evenly-distributed to each of the two clusters 430a and 430b. For example, as shown in FIG. 4, the partial segments 415a and 415c are assigned to the cluster 430a, and the partial segment 415b and another partial segment (not shown) are assigned to the cluster 430b.

Each of the clusters 430a and 430b can be configured to process the assigned partial segments using corresponding partial rows or columns of the matrix data 420. The process and operations performed in each cluster are similar to those described with respect to FIG. 2. Each cluster 430a and 430b can generate a respective partial sum by processing the assigned partial segments, where the partial sum can have a dimension of 1×output_{dim}. Each cluster 430a and 430b can be further configured to provide respective partial-sum vectors to the accumulator unit 455. The accumulator unit 455 can be configured to combine partial sum vectors from different clusters to generate an output vector and provide the output vector to the accumulator array 460. In some implementations, the accumulator array can have a dimension of 1×output_{dim}.

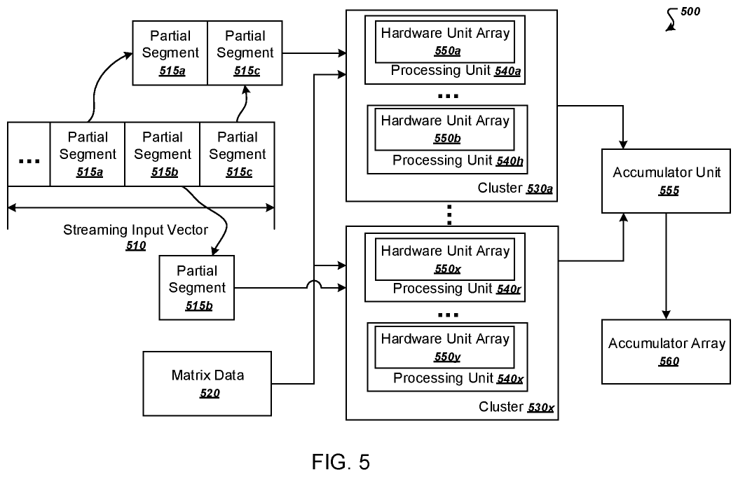

Referring to FIG. 5 and as described above, the example hardware architecture 500 can include multiple clusters 530a-x, each cluster having multiple processing units 540a-x, each processing unit having a respective hardware unit array 550a-y.

Similar to the process of FIG. 4, the described hardware component or system can be configured to divide a frame of an input vector at a time step into multiple partial segments 5151a-c. Each cluster 530a-x is substantially evenly assigned with a respective subset of partial segments. For example, as shown in FIG. 5, the partial segments 515a and 515c are assigned to the cluster 530a, and the partial segment 515b and another partial segment (not shown) are assigned to the cluster 530x.

Each cluster 530a-x performs a respective process and operations similar to those described with respect to FIG. 3. Each cluster 530a-x can generate a respective partial sum vector with a dimension of 1×output_{dim} and provide the respective partial sum to the accumulator unit 555. The accumulator unit 555 is configured to combine the corresponding partial sum vector and generate an output vector to provide to the accumulator array 560 for further operations. The accumulator array 560 can include a dimension of 1×output_{dim}.

Referring back to FIG. 1 and in connection with FIGS. 2-5, the architecture design system 100 can generate the hardware architectures 200, 300, 400, and 500 according to characteristics of different streaming input data. For example, when the streaming input data has a slower arrival rate (e.g., per second) or each frame has a small size (e.g., 120 pixels for an image frame), the architecture design system 100 can generate a hardware architecture similar to the hardware architecture 200 using a single processing unit in a cluster. As another example, when the streaming input data has a faster arrival rate (e.g., per millisecond), or each frame has a large size (e.g., 4000 pixels for an image frame) similar to hardware architectures 300, 400, or 500, having multiple processing elements in a cluster, or having multiple clusters.

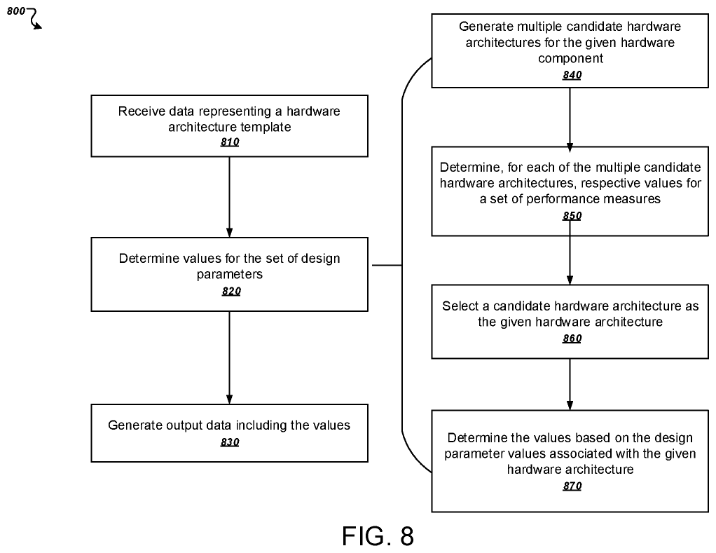

As described above, the example hardware architectures can have a set of design parameter values associated with at least one of the dimensions of a hardware unit arrays, a quantity of hardware unit arrays in a processing unit, a quantity of processing units in a cluster, and a quantity of clusters in a hardware architecture. The system is configured to determine a set of design parameter values using a search space formed by the set of design parameters, given the constraints of requirements of input data arrival rate, throughput, power consumption and available area or space. The details of determining a set of design parameter values are described in connection with FIG. 8.

Turning to the pre-stored matrix that is used for processing the input vector. The pre-stored matrix, also referred to as non-streaming matrix, is fetched or pre-fetched to on-device memory, e.g., an on-chip static random access memory (SRAM) unit. Because the size of the pre-stored matrix corresponds to the size of the input vector at a time step, a larger vector input requires a larger pre-stored matrix, which results in greater on-chip SRAM consumption.

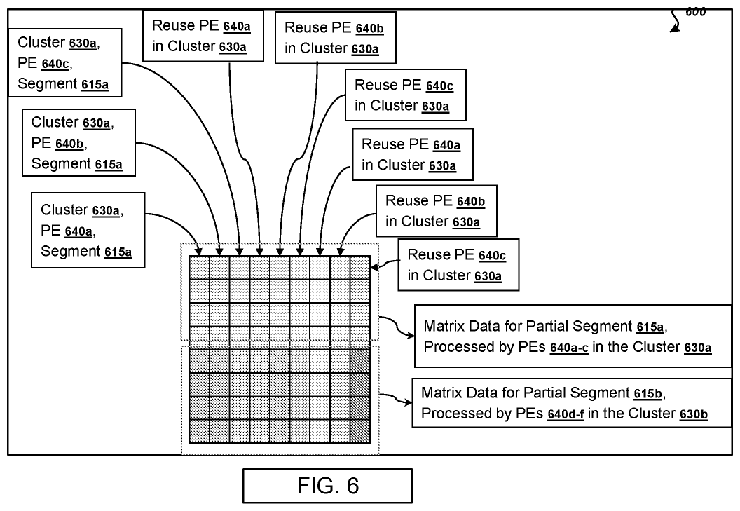

FIG. 6 illustrates an example data access pattern for a non-streaming matrix 600. For convenience, the data access pattern is associated with a process being performed by a system of one or more computers located in one or more locations. For example, a hardware component manufactured based on a hardware architecture generated from the architecture design system 100 of FIG. 1, appropriately programmed, can perform the process to generate the data access pattern.

In connection with FIG. 5, assuming the hardware architecture includes two clusters, e.g., cluster 630a and 630b, each cluster having three PEs (or processing units) 640a-c, each PE2 having a MAC array of size 4, the system can divide the example non-streaming matrix 600 into two portions illustrated in two rectangles as shown in FIG. 6. The top portion can be assigned to the cluster 630a and the bottom portion can be assigned to the cluster 630b.

The system can access a respective portion of the non-streaming matrix 600 to process a corresponding partial segment. The non-streaming matrix 600 has a dimension of 8 by 9. For example, when the cluster 630a receives a partial segment 615a of size 4 at the PE 640a. The cluster can also access the first column of the top portion (e.g., a partial column of the non-streaming matrix 600) and perform element-wise operations on each element of the partial segment 615a with a corresponding element in the partial column at the PE 640a to generate a first partial sum. Similarly, the cluster 630a can receive the partial segment 615a at the PE 640b and access the second column of the top portion, and perform operations of the partial segment 615a and the second column of the top portion using the PE 640b to generate a second partial sum. The cluster 630a can receive the partial segment 615a at the PE 640c and access the third column of the top portion, and perform operations of the partial segment 615a and the third column of the top portion using the PE 640c to generate a third partial sum. The first, second, and third partial sums can be arranged in a partial sum vector of dimension 3.

Then the PEs 640a-c can repeat the operations by accessing the fourth to sixth columns of the top portion to generate a second partial sum vector of dimension 3, and accessing the seventh to ninth columns of the top portion to generate a third partial sum vector of dimension 3. The cluster 630a can provide the first, second, and third partial sum vectors to an accumulator unit (e.g., the accumulator unit 555 of FIG. 5) to form an intermediate partial sum vector of dimension 1 by 9.

Turning to the bottom portion of the non-streaming matrix 600, the clusters 630b and its corresponding PEs 640d-f can access each column of the bottom portion to generate another intermediate partial sum vector of dimension 1 by 9. In some implementations, the system can provide the two intermediate partial sum vectors as the output data. Alternatively, the system can combine the partial sum vectors to generate an output data with a dimension of 1 by 9.

When a frame of streaming input data is in a matrix form, the system can perform operations following a process similar to the above-described techniques to process the frame of streaming input data. For example, if the input frame has a dimension of M rows and K columns and is received row by row at the hardware component or system, and the non-streaming matrix has a dimension of K rows and N columns. The system can process each row of the input matrix and load the non-streaming matrix for M times.

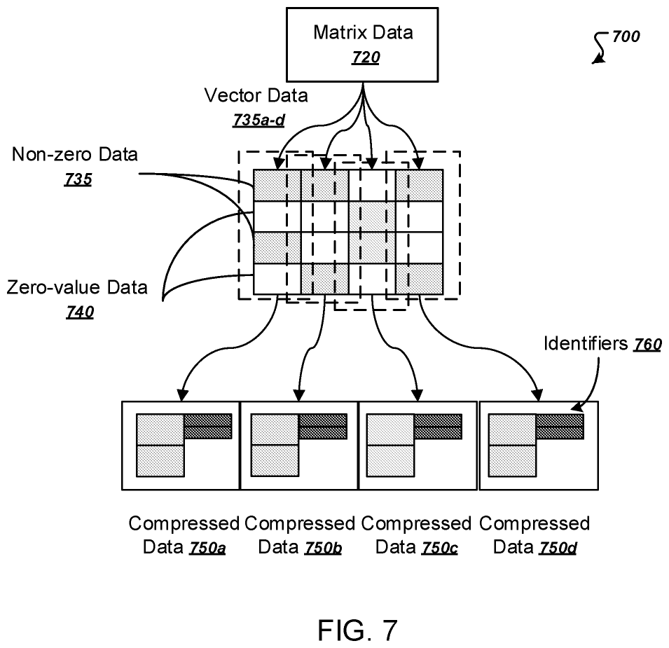

However, when the input frame is large in size and the non-streaming matrix is a sparse matrix with a particular sparsity level (i.e., a matrix with a particular percent of zero elements), loading or pre-fetching the non-streaming matrix of a large size for multiple times is inefficient regarding the power consumption and the computation resources. The techniques of processing a sparse non-streaming matrix are described in connection with FIG. 7.

FIG. 7 is an example process 700 of processing a sparse non-streaming matrix. For convenience, the process 700 is described as being performed by a system of one or more computers located in one or more locations. For example, a hardware component manufactured according to a hardware architecture generated from the architecture design system 100 of FIG. 1, appropriately programmed, can perform the process 700.

Because the non-streaming matrix is pre-determined and stored in an on-chip memory, the system can determine a sparsity level of the matrix and zero elements of the matrix. The sparsity level can be 10%, 20%, 50%, or another appropriate sparsity level.

In some implementations, the sparsity level can be a block sparsity ratio defined as K non-zero elements in a block of 1 by N vector. The block sparsity ratio for the non-streaming matrix can be tuned for respective tasks, such as face-detection, gaze detection, or depth map generation. Since the sparsity level can be pre-determined, the hardware component or system described in this specification can pre-process and compress the sparse matrix offline.

In addition, the described techniques can also determine a segmentation size (dimension size D) for dividing the input vector based on the per-determined sparsity level and the characteristics of the streaming input data. After determining the dimension size D, the system can access a non-streaming matrix in the granularity of D elements and encode non-zero elements for each partial column or row of the non-streaming matrix. In this way, the described techniques can maximize the utilization of the hardware unit arrays and reduce metadata storage overheads and the complexity of decoding hardware indices than using existing compressed formats, e.g., the compressed sparse row (CSR) format or the compressed sparse column (CSC) format.

As shown in FIG. 7, an example non-streaming matrix (e.g., matrix data 720) includes non-zero elements 735 depicted in shaded regions and zero elements 740 depicted in white regions. For example, each of the vector data 735a-d includes four elements. The first and third elements of the vector data 735a are non-zero, and the second and fourth elements of the vector data 735a are zero. The first and fourth elements of the vector data 735b are non-zero, and the second and third elements of the vector data 735b are zero. The second and third elements of the vector data 735c are non-zero, and the first and fourth elements of the vector data 735c are zero.

The system can process each vector data 735a-d to generate a respective compressed data 750a-d, where each compressed data includes only non-zero elements with identifiers 760 indicating a relative location with respect to the original vector data 735a-d. The identifiers 760 can be generated based on an index mapping or a bitmap. After receiving a partial segment at a PE, the system can select values from the partial segment using the identifiers to process the partial segment. The values selected from the partial segments correspond to non-zero elements in corresponding compressed data 750a-d.

For example, the compressed data 750) generated based on the vector data 735a can include only non-zero data, i.e., the first and third elements, and identifiers 760 associated with the first and third elements. The identifiers 760 are configured to indicate that the first element of the compressed data 750) corresponds to the first location of the vector data 735a, and the second element of the compressed data 750a corresponds to the third location of the vector data 735a. When processing the vector data 735a with a corresponding input partial segment, the system can only select values from the partial segment that is located in the first and third locations of the input partial segment and perform element-wise operations of the selected values with the corresponding non-zero elements in the compressed data 750a.

Furthermore, the described techniques can support both dense computations and sparse computation. More specifically, the described techniques can switch a mode for the hardware component to process the streaming input data between a dense mode and a sparse mode, in response to determining a change of an input matrix stored in the hardware component when the hardware component is performing operations to process the streaming input data. For example, the manufactured hardware component can include a control and status register (CSR) used to switch the hardware component to process the streaming input data with a new non-streaming data from a dense matrix mode to a sparse matrix mode, in response to determining that the new non-streaming matrix qualifies a threshold sparsity value for the sparse-matrix mode. Note that the identifiers are used only for the sparse matrix mode.

FIG. 8 is a flow diagram of an example process 800 of generating an output data using a hardware architecture template. For convenience, the process 800 is described as being performed by a system of one or more computers located in one or more locations. For example, a system, e.g., the architecture design system 100 of FIG. 1, appropriately programmed, can perform the process 800.

The system receives data representing a hardware architecture template (810). As described above, the hardware architecture template is configured to include a set of configurable design parameters and to instantiate a hardware architecture based on determined design parameter values. The hardware architecture can be used to manufacture a hardware component that is configured to process particular streaming input data. The set of design parameters include two or more of (i) a quantity of clusters in a hardware architecture, (ii) a quantity of processing units in each cluster, and (iii) a size of a hardware unit array in each processing unit.

The system determines, for a hardware architecture for manufacturing a hardware component, values for the set of configurable design parameters (820). The determination of values is based at least in part on characteristics of the respective streaming input data for the given hardware component. The details of the determination process are described in connection with steps 840-870.

The system generates output data including the values (830). In some implementations, the output data can include an instantiated hardware architecture generated by setting the set of configurable design parameters with the determined values for the hardware template. Alternatively, the output data can include both obtained design parameter values and a corresponding hardware architecture generated based on the values from the template. The system can further provide the output data for manufacturing the hardware component based on the hardware architecture.

To generate the values for the set of configurable design parameters, the system first generates multiple candidate hardware architectures based on a search space for the set of configurable design parameters (840). As described above, the search space is based on the set of configurable design parameters and bounded by possible parameter values based on available computation resources, power consumption, and on-chip area usage. The system can generate multiple candidate hardware architectures with a respective set of design parameter values among one or more possible sets of design parameter values.

The one or more possible sets of design parameter values can be determined using one or more different search algorithms. For example, the system can perform random search, exhaustive search, or genetic search algorithm.

One example range for the set of design parameters can be 5 clusters, 20 PEs, and 100 MAC unit arrays for manufacturing a hardware component. In other words, the candidate hardware components can have a quantity of clusters ranging from 1 to 5, each cluster can have a quantity of PEs ranging from 1 to 20, and each PE can have 1-100 MAC unit arrays each with a respective size. The system can generate multiple candidate hardware architectures using the above-noted search algorithms to search multiple possible values from the example range and apply each set to instantiate a respective hardware component using the template. For example, the system can start with the smallest values for the set of design parameters, and gradually increase values for one or more of the design parameters. The system can stop searching once obtaining a set of design parameter values that are suitable for the throughput requirement.

In some implementations, the system can search for parameter values associated with a size of hardware unit arrays, a quantity of hardware unit arrays in a PE, and a quantity of PEs in a cluster, but not searching or increasing a quantity of clusters until determining a turning point where further increasing the size of hardware unit arrays or the quantity of PEs per cluster would adversely affect the computation clock rate or cause logic congestion, i.e., the size of the hardware unit array and the quantity of processing units per cluster are at a scalability limit for the cluster. In this way, the system can arrange more hardware units and PEs and minimize the quantity of clusters for instantiating a hardware architecture to satisfy the required throughput.

The system determines, for each of the multiple candidate hardware architectures, respective values for a set of performance measures (850). The respective values for the set of performance values are determined for each candidate hardware architecture using a performance model (or a cost model). The performance values are each associated with a numerical value representing a cost or combinations of multiple costs. The cost can represent a level of latency, throughput, power consumption, on-chip area usage, computation resources usage, or any suitable combinations thereof.

The performance model can be any suitable model for processing a hardware architecture with a set of design parameter values. The performance model can be an analytical model, a machine learning based model, or a hardware simulation model, to name just a few examples.

An analytical model can generally determine a topology of the hardware architecture, e.g., interfaces, wiring, quantities of computing units such as multipliers, adders, and logic units, and determine performance values for the hardware architecture based on the topology. One example analytical model can be a roofline-based model that generates performance values for a hardware architecture as a function of machine peak performance, machine peak bandwidth, and arithmetic intensity. The output of the roofline-based model can be a functional curve representing a performance upper bound (e.g., “ceiling”) for the hardware architecture under particular computation requirements or resource limitations. The roofline-based model can automatically determine “bottleneck” factors for the overall performance and output performance values representing a level of latency, throughput, or power consumption, or both, as described above.

Alternatively, a performance model can be a machine learning model trained with labeled training samples (e.g., supervised learning). The training sample can be generated using high-level synthesis and register-transfer level simulation. The trained machine learning model is configured to generate a prediction of performance values and can be any suitable machine learning model, e.g., a multi-layer perceptron model.

In addition, a performance model can be a simulation model. The simulation model can generate an estimate of power computation and throughput based on the characteristics of the hardware architecture given one or more randomized input stimuli.

The system selects a candidate hardware architecture as the hardware architecture for the hardware component (860). More specifically, the system can select the enhanced hardware architecture based at least in part on the performance values. As described above, the hardware architecture can be a candidate hardware architecture that has the highest performance values. Alternatively, the hardware architecture can have decent performance values but require the least computational resources.

The system determines the values based on the design parameter values associated with the selected candidate hardware architecture (870)). The determined values can be included in the output data provided for instantiating a hardware architecture using the template or used for manufacturing a hardware component.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, e.g., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program which may also be referred to or described as a program, software, a software application, an app, a module, a software module, a script, or code) can be written in any form of programming language, including compiled or interpreted languages, or declarative or procedural languages, and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

For a system of one or more computers to be configured to perform particular operations or actions means that the system has installed on it, software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

As used in this specification, an “engine,” or “software engine,” refers to a software implemented input/output system that provides an output that is different from the input. An engine can be an encoded block of functionality, such as a library, a platform, a software development kit (“SDK”), or an object. Each engine can be implemented on any appropriate type of computing device, e.g., servers, mobile phones, tablet computers, notebook computers, music players, e-book readers, laptop or desktop computers, PDAs, smart phones, or other stationary or portable devices, that includes one or more processors and computer readable media. Additionally, two or more of the engines may be implemented on the same computing device, or on different computing devices.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few:

Computer-readable media suitable for storing computer program instructions and data include all forms of non-volatile memory, media and memory devices, including by way of example semiconductor memory devices, e.g., EPROM, EEPROM, and flash memory devices: magnetic disks, e.g., internal hard disks or removable disks: magneto-optical disks: and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and pointing device, e.g., a mouse, trackball, or a presence sensitive display or other surface by which the user can provide input to the computer. Other kinds of devices can be used to provide for interaction with a user as well: for example, feedback provided to the user can be any form of sensory feedback, e.g., visual feedback, auditory feedback, or tactile feedback: and input from the user can be received in any form, including acoustic, speech, or tactile input. In addition, a computer can interact with a user by sending documents to and receiving documents from a device that is used by the user: for example, by sending web pages to a web browser on a user's device in response to requests received from the web browser. Also, a computer can interact with a user by sending text messages or other forms of message to a personal device, e.g., a smartphone, running a messaging application, and receiving responsive messages from the user in return.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

In addition to the embodiments described above, the following embodiments are also innovative:

Embodiment 1 is a method including receiving data representing a hardware architecture template for generating hardware architectures for hardware components that are configured to perform operations on respective streaming input data, wherein the hardware architecture template includes a set of configurable design parameters including two or more of (i) a quantity of clusters in a hardware architecture, (ii) a quantity of processing units in each cluster, and (iii) a size of a hardware unit array in each processing unit: determining, for a given hardware architecture for a given hardware component, values for the set of configurable design parameters based at least in part on characteristics of the respective streaming input data for the given hardware component, the determining including: generating, based on a search space for the set of configurable design parameters, a plurality of candidate hardware architectures for the given hardware component using the hardware architecture template, wherein each candidate hardware architecture includes respective design parameter values for the set of configurable design parameters: determining, for each of the plurality of candidate hardware architectures, respective values for a set of performance measures associated with the candidate hardware architecture based on a performance model and the characteristics of the respective streaming input data for the given hardware component: selecting, as the given hardware architecture, a candidate hardware architecture from the plurality of candidate hardware architectures based at least in part on the respective values for the set of performance measures: and determining, as the values for the set of configurable design parameters of the given hardware architecture, design parameter values associated with the selected candidate hardware architecture: and generating output data indicating the values for the set of design parameters of the given hardware architecture.

Embodiment 2 is the method of embodiment 1, further including: providing the output data to the hardware architecture template: instantiating the given hardware architecture based on the values for the set of design parameters of the given hardware architecture: and manufacturing the given hardware component based on the given hardware architecture.

Embodiment 3 is the method of embodiment 1 or 2, wherein the characteristics of the respective streaming input data for the given hardware component includes an arrival rate of each frame and a size of each frame of the respective streaming input data for the given hardware component.

Embodiment 4 is the method of any one of embodiments 1-3, wherein the set of performance measures includes measures at least one of: latency, power consumption, resource usage, or throughput for processing the respective streaming input data for the given hardware component, wherein the performance model includes at least one of an analytical cost model, a machine learning cost model, or a hardware simulation model.

Embodiment 5 is the method of any one of embodiments 1-4, wherein the respective streaming input data for the given hardware component comprises streaming image frames collected by an image sensor according to a time sequence.

Embodiment 6 is the method of embodiment 5, wherein characteristics of the streaming image frames comprise at least one of a particular arrival rate for image frames and a respective image resolution for each of the image frames.

Embodiment 7 is the method of embodiment 5, wherein characteristics of the streaming image frames comprise a blanking period comprising at least one of a vertical blanking period or a horizontal blanking period.

Embodiment 8 is the method of embodiment 5, wherein characteristics of the streaming image frames comprise a pixel format, wherein the pixel format comprises a RGB or YUV color format.

Embodiment 9 is the method of any one of embodiments 1-8, wherein the respective streaming input data for the given hardware component comprises streaming audio collected by an audio sensor,

Embodiment 10 is the method of claim 9, wherein characteristics of the streaming input data comprise at least one of a particular sample rate for the streaming audio, a bit depth of the streaming audio, a bit rate of the streaming audio, or an audio format of the streaming audio.

Embodiment 11 is the method of any one of embodiments 1-10, wherein performing operations on the respective streaming input data using the given hardware component includes: for each frame of the streaming input data: segmenting an input vector of the frame into a plurality of partial vectors each including non-overlapping values of the input vector: and for each partial vector of the plurality of partial vectors, assigning the partial vector to a respective cluster of a plurality of clusters that each has a respective quantity of processing units and each processing unit has a hardware unit array of a respective size corresponding to the values for the set of design parameters of the given hardware architecture: multiplying, by the respective cluster, each value of the partial vector with a corresponding value of a partial row of a matrix stored in memory to generate a respective partial sum: and storing the respective partial sum in an accumulator array.

Embodiment 12 is the method of embodiment 11, wherein performing operations on the respective streaming input data for the given hardware component using the given hardware component includes performing the operations based on a sparsity level of the matrix stored in memory.

Embodiment 13 is the method of any one of embodiments 1-12, wherein the performing operations are switched between a dense matrix mode and a sparse matrix mode, wherein the switching process is controlled by a control and status (CSR) register.

Embodiment 14 is the method of embodiment 11, wherein when generating the corresponding values of the partial row of the matrix stored in memory is performed under a sparse matrix mode, and wherein the generating further includes: determining non-zero values in the partial row of the matrix stored in memory: generating identifiers that indicate positions of the non-zero values of the partial row in the matrix, wherein the identifiers include indices or bitmaps: and generating a compressed vector of non-zero values associated with corresponding identifiers as the corresponding values of the partial row of the matrix.

Embodiment 15 is the method of embodiment 14, further including: selecting values of the partial vector corresponding to the compressed vector based on the corresponding identifiers: and multiplying each of the selected values of the partial vector with a corresponding non-zero value of the compressed vector.

Embodiment 16 is the method of any one of embodiments 1-15, wherein the given hardware architecture includes data indicating an upper-bound sparsity level for one or more matrices stored in memory, wherein the given hardware architecture is configured to be re-instantiated dynamically to process the streaming input data with a second matrix of the one or more matrices that has a sparsity level different from a first matrix of the one or more matrices.

Embodiment 17 is the method of any one of embodiments 1-16, wherein generating, based on the search space for the set of configurable design parameters, the plurality of candidate hardware architectures using the hardware architecture template includes exploring the search space for the set of design parameters using at least one of: a random search algorithm, an exhaustive search algorithm, or a genetic algorithm.

Embodiment 18 is the method of any one of embodiments 1-17, wherein exploring the search space for the set of configurable design parameters including: exploring design parameter values corresponding to the size of a hardware unit array in each processing unit and the quantity of processing units in a cluster: determining that the design parameter values corresponding to the size of the hardware unit array and the quantity of processing units in the cluster are at a scalability limit for the cluster: and in response, exploring design parameter values corresponding to the quantity of clusters.

Embodiment 19 is a system including one or more computers and one or more storage devices storing instructions that are operable, when executed by the one or more computers, to cause the one or more computers to perform the method of any one of embodiments 1 to 18.

Embodiment 20 is a computer storage medium encoded with a computer program, the program including instructions that are operable, when executed by data processing apparatus, to cause the data processing apparatus to perform the method of any one of embodiments 1 to 18.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain cases, multitasking and parallel processing may be advantageous.

1. A method comprising:
receiving data representing a hardware architecture template for generating hardware architectures for hardware components that are configured to perform operations on respective streaming input data, wherein the hardware architecture template comprises a set of configurable design parameters comprising two or more of (i) a quantity of clusters in a hardware architecture, (ii) a quantity of processing units in each cluster, and (iii) a size of a hardware unit array in each processing unit;
determining, for a given hardware architecture for a given hardware component, values for the set of configurable design parameters based at least in part on characteristics of the respective streaming input data for the given hardware component, the determining comprising:
generating, based on a search space for the set of configurable design parameters, a plurality of candidate hardware architectures for the given hardware component using the hardware architecture template, wherein each candidate hardware architecture comprises respective design parameter values for the set of configurable design parameters;
determining, for each of the plurality of candidate hardware architectures, respective values for a set of performance measures associated with the candidate hardware architecture based on a performance model and the characteristics of the respective streaming input data for the given hardware component;
selecting, as the given hardware architecture, a candidate hardware architecture from the plurality of candidate hardware architectures based at least in part on the respective values for the set of performance measures; and
determining, as the values for the set of configurable design parameters of the given hardware architecture, design parameter values associated with the selected candidate hardware architecture; and
generating output data indicating the values for the set of design parameters of the given hardware architecture.

2. The method of claim 1, further comprising:
providing the output data to the hardware architecture template;
instantiating the given hardware architecture based on the values for the set of design parameters of the given hardware architecture; and
manufacturing the given hardware component based on the given hardware architecture.

3. The method of claim 1, wherein the characteristics of the respective streaming input data for the given hardware component comprises an arrival rate of each frame and a size of each frame of the respective streaming input data for the given hardware component.

4. The method of claim 1, wherein the set of performance measures comprises measures at least one of: latency, power consumption, resource usage, or throughput for processing the respective streaming input data for the given hardware component, wherein the performance model comprises at least one of an analytical cost model, a machine learning cost model, or a hardware simulation model.

5. The method of claim 1, wherein the respective streaming input data for the given hardware component comprises streaming image frames collected by an image sensor according to a time sequence.

6. The method of claim 5, wherein characteristics of the streaming image frames comprise at least one of a particular arrival rate for image frames and a respective image resolution for each of the image frames.

7. The method of claim 5, wherein characteristics of the streaming image frames comprise a blanking period comprising at least one of a vertical blanking period or a horizontal blanking period.

8. The method of claim 5, wherein characteristics of the streaming image frames comprise a pixel format, wherein the pixel format comprises a RGB or YUV color format.

9. The method of claim 1, wherein the respective streaming input data for the given hardware component comprises streaming audio collected by an audio sensor.

10. The method of claim 9, wherein characteristics of the streaming input data comprise at least one of a particular sample rate for the streaming audio, a bit depth of the streaming audio, a bit rate of the streaming audio, or an audio format of the streaming audio.

11. The method of claim 1, wherein performing operations on the respective streaming input data using the given hardware component comprises:
for each frame of the streaming input data:
segmenting an input vector of the frame into a plurality of partial vectors each including non-overlapping values of the input vector; and
for each partial vector of the plurality of partial vectors,
assigning the partial vector to a respective cluster of a plurality of clusters that each has a respective quantity of processing units and each processing unit has a hardware unit array of a respective size corresponding to the values for the set of design parameters of the given hardware architecture;
multiplying, by the respective cluster, each value of the partial vector with a corresponding value of a partial row of a matrix stored in memory to generate a respective partial sum; and
storing the respective partial sum in an accumulator array.

12. The method of claim 11, wherein performing operations on the respective streaming input data for the given hardware component using the given hardware component comprises performing the operations based on a sparsity level of the matrix stored in memory.

13. The method of claim 1, wherein the performing operations are switched between a dense matrix mode and a sparse matrix mode, wherein a switching process that switches between the dense matrix mode and the sparse matrix mode is controlled by a control and status (CSR) register.

14. The method of claim 11, wherein when generating the corresponding values of the partial row of the matrix stored in memory is performed under a sparse matrix mode, and wherein the generating further comprises:
determining non-zero values in the partial row of the matrix stored in memory;
generating identifiers that indicate positions of the non-zero values of the partial row in the matrix, wherein the identifiers comprise indices or bitmaps; and
generating a compressed vector of non-zero values associated with corresponding identifiers as the corresponding values of the partial row of the matrix.

15. The method of claim 14, further comprising:
selecting values of the partial vector corresponding to the compressed vector based on the corresponding identifiers; and
multiplying each of the selected values of the partial vector with a corresponding non-zero value of the compressed vector.

16. The method of claim 1, wherein the given hardware architecture comprises data indicating an upper-bound sparsity level for one or more matrices stored in memory, wherein the given hardware architecture is configured to be re-instantiated dynamically to process the streaming input data with a second matrix of the one or more matrices that has a sparsity level different from a first matrix of the one or more matrices.

17. The method of claim 1, wherein generating, based on the search space for the set of configurable design parameters, the plurality of candidate hardware architectures using the hardware architecture template comprises exploring the search space for the set of design parameters using at least one of: a random search algorithm, an exhaustive search algorithm, or a genetic algorithm.

18. The method of claim 1, wherein exploring the search space for the set of configurable design parameters comprising:
exploring design parameter values corresponding to the size of a hardware unit array in each processing unit and the quantity of processing units in a cluster;
determining that the design parameter values corresponding to the size of the hardware unit array and the quantity of processing units in the cluster are at a scalability limit for the cluster; and
in response, exploring design parameter values corresponding to the quantity of clusters.

19. One or more non-transitory computer-readable storage media storing instructions that when executed by one or more computers cause the one or more computers to perform operations comprising:
receiving data representing a hardware architecture template for generating hardware architectures for hardware components that are configured to perform operations on respective streaming input data, wherein the hardware architecture template comprises a set of configurable design parameters comprising two or more of (i) a quantity of clusters in a hardware architecture. (ii) a quantity of processing units in each cluster, and (iii) a size of a hardware unit array in each processing unit;
determining, for a given hardware architecture for a given hardware component, values for the set of configurable design parameters based at least in part on characteristics of the respective streaming input data for the given hardware component, the determining comprising:
generating, based on a search space for the set of configurable design parameters, a plurality of candidate hardware architectures for the given hardware component using the hardware architecture template, wherein each candidate hardware architecture comprises respective design parameter values for the set of configurable design parameters;
determining, for each of the plurality of candidate hardware architectures. respective values for a set of performance measures associated with the candidate hardware architecture based on a performance model and the characteristics of the respective streaming input data for the given hardware component;
selecting, as the given hardware architecture, a candidate hardware architecture from the plurality of candidate hardware architectures based at least in part on the respective values for the set of performance measures; and
determining, as the values for the set of configurable design parameters of the given hardware architecture, design parameter values associated with the selected candidate hardware architecture; and
generating output data indicating the values for the set of design parameters of the given hardware architecture.

20. A system comprising one or more computers and one or more storage devices storing instructions that when executed by one or more computers cause the one or more computers to perform operations comprising:
receiving data representing a hardware architecture template for generating hardware architectures for hardware components that are configured to perform operations on respective streaming input data, wherein the hardware architecture template comprises a set of configurable design parameters comprising two or more of (i) a quantity of clusters in a hardware architecture. (ii) a quantity of processing units in each cluster, and (iii) a size of a hardware unit array in each processing unit;
determining, for a given hardware architecture for a given hardware component, values for the set of configurable design parameters based at least in part on characteristics of the respective streaming input data for the given hardware component, the determining comprising:
generating, based on a search space for the set of configurable design parameters, a plurality of candidate hardware architectures for the given hardware component using the hardware architecture template, wherein each candidate hardware architecture comprises respective design parameter values for the set of configurable design parameters;
determining, for each of the plurality of candidate hardware architectures, respective values for a set of performance measures associated with the candidate hardware architecture based on a performance model and the characteristics of the respective streaming input data for the given hardware component;
selecting, as the given hardware architecture, a candidate hardware architecture from the plurality of candidate hardware architectures based at least in part on the respective values for the set of performance measures; and
determining, as the values for the set of configurable design parameters of the given hardware architecture, design parameter values associated with the selected candidate hardware architecture; and
generating output data indicating the values for the set of design parameters of the given hardware architecture.
